(19) United States
(12) Patent Application Publication
(10) Pub. No.: US 2020/0256228 A1
(43) Pub. Date: Aug. 13, 2020

(54) Vacuum Pumps For Single And Multi-Process Chamber Flow Stream Sharing

(71) Applicant: Applied Materials, Inc., Santa Clara, CA (US)

(72) Inventors: Michael Rice, Pleasanton, CA (US); Sanjeev Baluja, Campbell, CA (US); Joseph AuBuchon, San Jose, CA (US); Hari Ponnekanti, San Jose, CA (US); Mario D. Silvetti, Morgan Hill, CA (US); Kevin Griffin, Livermore, CA (US)

(73) Assignee: Applied Materials, Inc., Santa Clara, CA (US)

(21) Appl. No.: 16/789,796

(22) Filed: Feb. 13, 2020

Related U.S. Application Data
(60) Provisional application No. 62/805,284, filed on Feb. 13, 2019.

(51) Int. Cl. F01N 1/16; F01N 11/00; F01N 13/08

(52) U.S. Cl. CPC F01N 1/166; F01N 2900/1406; F01N 13/08; F01N 11/002

(57) ABSTRACT

Exhaust systems for handling multiple effluent streams are described. Some embodiments include pressure drops to prevent perturbations from one effluent source from affecting a second effluent source. Some embodiments incorporate an exhaust assembly with multiple inlets and pumps and a single outlet. The exhaust assembly includes shared auxiliary components like purge and cooling systems.

### CROSS-REFERENCE TO RELATED APPLICATIONS

This application claims priority to U.S. Provisional Application No. 62/805,284, filed Feb. 13, 2019, the entire disclosure of which is hereby incorporated by reference herein.

### TECHNICAL FIELD

The present disclosure relates generally to processing systems with multiple exhaust streams. More specifically, embodiments of the disclosure are directed to processing systems with multiple exhaust flow streams with shared pumping.

### BACKGROUND

Current processing tools have multiple pumping/exhaust systems to prevent incompatible gases from mixing. These pumping/exhaust systems can be extremely large, requiring a significant footprint for multiple chambers. Combining exhaust streams can reduce the footprint of the processing system. However, issues arise with pressure spiking in one chamber while another chamber on a shared exhaust system is under heavy load.

Accordingly, there is a need in the art for apparatus and methods to exhaust multiple gas streams while reducing the footprint needed for the exhaust system.

### SUMMARY

One or more embodiments of the disclosure are directed to exhaust systems comprising: at least one first chamber connection line; a first chamber pressure drop downstream of and in fluid communication with each of the at least one first chamber connection line; at least one second chamber connection line; a second chamber pressure drop downstream of and in fluid communication with each of the at least one second chamber connection lines; and an exhaust pump in fluid communication with and downstream of the first chamber pressure drop and second chamber pressure drop.

Additional embodiments are directed to exhaust systems comprising: at least one first chamber connection line; at least one second chamber connection line; and an exhaust pump assembly comprising a first inlet, a second inlet, a first pump in fluid communication with the first inlet, a second pump in fluid communication with the second inlet, a first outlet line in fluid communication with and downstream of the first pump, a second outlet line in fluid communication with and downstream of the second pump, an exhaust pump assembly outlet line in fluid communication with and downstream of the first outlet line and the second outlet line so that a fluid flowing through the first outlet line and the second outlet line coflow through the exhaust pump assembly outlet line and through an outlet in the exhaust pump assembly.

Further embodiments of the disclosure are directed to non-transitory computer readable medium including instructions, that, when executed by a controller of an exhaust system, causes the exhaust system to perform one or more operations selected from: a configuration to measure pressure within an effluent stream using one or more pressure monitors; a configuration to control one or more valves; a configuration to evaluate valve control parameters based on pressure measurements from the pressure monitors; a configuration to control the pumps and/or pump assembly; and/or a configuration to control a flow of water into the water inlet lines or purge gas into the purge lines.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a schematic of an exhaust system with pressure drops in accordance with some embodiments of the present disclosure; and

FIG. 2 depicts a schematic of an exhaust system with an exhaust assembly in accordance with some embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the terms “precursor”, “reactant”, “reactive gas” and the like are used interchangeably to refer to any gaseous species that can react with the substrate surface.

Those skilled in the art will understand that the use of ordinals such as “first” and “second” to describe process regions do not imply a specific location within the processing chamber, or order of exposure within the processing chamber.

Embodiments of the disclosure provide a single integrated vacuum pump module to manage one or more gas effluent streams from a single chamber or multiple streams from multiple chambers commonly used in low pressure chemical processing such as Atomic layer Deposition (ALD) or Chemical Vapor Deposition (CVD) related equipment.

Some embodiments of the disclosure provide a pump stack module with two or more separate lower pressure gas inputs and a higher pressure output which can combine the gas streams with a single outlet, or keep the gas streams separate through the pump with dedicated outlets. If the gas flow streams are combined, than there will be a pressure drop stage or baffle that reduces spikes between combined streams all within the pump module.

Some embodiments of the disclosure advantageously provide an apparatus to combine effluent flow streams from multiple sources into a single pump module. Some embodiments advantageously provide exhaust apparatus with reduced floor footprints when having one pump for each effluent flow stream as is currently done. Some embodiments advantageously provide exhaust apparatus with reduced pressure spikes between shared streams. Some embodiments advantageously provide integrated modules to allow vertical stack of pump assemblies, as well as pressure spike mitigation where needed. Some embodiments advantageously provide reduction of cost and complexity from combining cooling water, power and purge gas and related facility utilities.

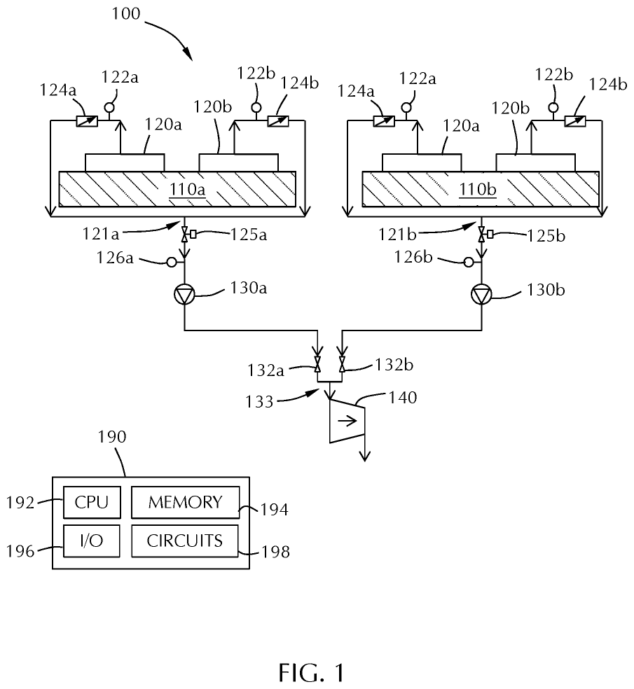

FIG. 1 illustrates a first embodiment of the apparatus in which multiple chambers or fluid streams are exhausted through a single exhaust pump. The illustrated apparatus includes two process chambers 110a, 110b with two first exhaust lines 120a and two second exhaust lines 120b. Each of the first exhaust lines 120a and second exhaust lines 120b from the first process chamber 110a connect at a junction 121a upstream of a first pressure drop 130a. Each of the first exhaust lines 120a and second exhaust lines 120b from the second process chamber 110b connect at a junction 121b upstream of a second pressure drop 130b.

The pressure drops 130a, 130b are any component that can restrict pressure spikes from one chamber from reaching the other chamber. Stated differently, the pressure drops prevent pressure perturbations. In some embodiments, the pressure drops comprise one or more of baffles or pumps. Suitable baffles include, but are not limited to, labyrinthine baffles. Suitable pumps include, but are not limited to, turbo pumps and roots blowers. Downstream of the first pressure drop 130a and second pressure drop 130b the effluent streams combine and flow into a single exhaust pump 140.

The illustrated embodiments include optional pressure monitors 122a, 122b, 126a, 126b. Each of the pressure monitors are independently selected from pressure gauges or flow sensors. The system illustrated includes pressure monitors 122a, 122b positioned downstream of the exhaust lines 120a, 120b and upstream of the junction 121a, 121b.

The illustrated embodiment also includes optional pressure control valves 124a, 124b connected to the first exhaust line 120a and second exhaust line 120b, respectively. The pressure control valves 124a, 124b of some embodiments are configured to control the pressure or flow exiting the process chambers 110a, 110b through the exhaust lines 120a, 120b.

The illustrated embodiment also includes optional valves 125a, 125b, 132a, 132b. The optional components can be positioned at any suitable location. In the illustrated embodiment, a valve 125a is positioned downstream of the junction 121a and a valve 125b is positioned downstream of the junction 121b. The valve 125a of some embodiments is upstream of a pressure monitor 126a and valve 125b is upstream of pressure monitor 126b so that the pressure monitor 126a, 126b is between valve 125a, 125b, respectively, and pressure drop 130a, 130b, respectively. The valves 125a, 125b of some embodiments are positioned downstream of the pressure monitors 126a, 126b, respectively, so that the valves 125a, 125b are between the respective pressure monitors 126a, 126b and pressure drops 130a, 130b.

In some embodiments, data is collected from the pressure monitors 122a, 122b and is used to determine valve control parameters for one or more of the pressure control valves 124a, 124b or valves 125a, 125b, 132a, 132b. The system of some embodiments comprises a controller 190 connected to one or more of the pressure drops 130a, 130b, exhaust pump 140, or pressure control valves 124a, 124b, or valves 125a, 125b, 132a, 132b. In some embodiments, the controller 190 is configured to open and close the valves 125a, 125b in response to data collected by one or more sensors (e.g., pressure monitors 122a, 122b, 126a, 126b) within the system.

In some embodiments, each junction 121a, 121b has a valve 125a, 125b, respectively, downstream of the junction, and a pressure monitor 126a, 126b, respectively, downstream of the valve. In some embodiments of this type, the valves 125a, 125b are controlled by controller 190 based on data provided by or collected from pressure monitors 126a, 126b so that the pressure and gas flows from the exhaust systems entering the pressure drops 130a, 130b, respectively, can be controlled. In some embodiments, valve 132a, 132b is downstream of pressure drop 130a, 130b, respectively, and upstream of pump 140. In some embodiments, a pressure monitor (not shown) is positioned between the pressure drops 130a, 130b and the pump 140.

In some embodiments, one junction 121a or 121b has a valve 125a or 125b, respectively, downstream thereof and the other junction does not have a valve between the junction and the pressure monitor. In some embodiments of this sort, the valves is controlled based on the pressure measurements from the pressure monitors of both exhaust streams passing into the pump 140 so that the flow through each exhaust line is controlled by one valve.

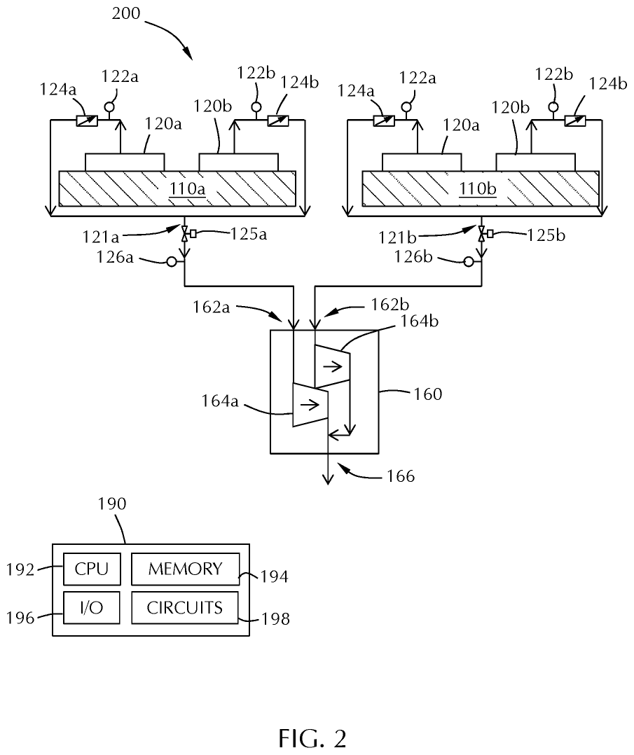

FIG. 2 illustrates a second embodiment in which an exhaust pump assembly 160 handles the effluent from each of the process chambers 110a, 110b. The exhaust pump assembly 160 of some embodiments has an equal number of pumps 164a, 164b as effluent streams. In some embodiments, there are fewer pumps than effluent streams. For example, the illustrated embodiment has two effluent streams from two processing chambers that flow into two pumps. Whereas, the embodiment of FIG. 1 has two effluent streams from two processing chambers flow into one pump. In some embodiments, the system includes a pressure monitor 126a, 126b upstream of the pressure drop 130a, 130b, respectively, with a valve 132a, 132b downstream of the pressure drop 130a, 130b, and upstream of a pre-pump junction 133.

The exhaust pump assembly 160 of the embodiment of FIG. 2 has an inlet for each effluent stream. In the illustrated embodiment, the first effluent stream enters the assembly 160 through the first inlet 162a and the second effluent stream enters the assembly 160 through the second inlet 162b. The first inlet 162a is in fluid communication with a first pump 164a and the second inlet 162b is in fluid communication with a second pump 164b. The effluent exiting the first pump 164a and the second pump 164b are combined at a junction and flow through a single outlet 166.

The exhaust pump assembly 160 can include one or more shared resources to decrease the space required for the components. For example, shared water lines (i.e., coolant lines) or shared purge lines. This allows for a single water inlet/water outlet pair and single purge inlet/purge outlet pair with split flows within the assembly 160. Thus, for example, a single water source can be used to cool multiple pumps within the assembly 160 with a single outlet for the water.

Some embodiments combine the pressure drops 130 of FIG. 1 with the pump assembly 160 of FIG. 2 so that there are fewer pumps in the assembly than chambers being exhausted.

Some embodiments of the disclosure include at least one controller 190 coupled to one or more of the pump 140, pressure control valves 124a, 124b, valves 125a, 125b, 132a, 132b, pressure monitors 122a, 122b, 126a, 126b, or exhaust pump assembly 160. In some embodiments, there are more than one controller 190 connected to the individual valves, measurement components or pumps and a primary control processor is coupled to each of the separate controllers to control the system 100, 200. The controller 190 may be one of any form of general-purpose computer processor, microcontroller, microprocessor, etc., that can be used in an industrial setting for controlling various chambers and sub-processors.

The at least one controller 190 of some embodiments has a processor 192, a memory 194 coupled to the processor 192, input/output devices 196 coupled to the processor 192, and support circuits 198 to communication between the different electronic components. The memory 194 of some embodiments includes one or more of transitory memory (e.g., random access memory) or non-transitory memory (e.g., storage).

The memory 194, or computer-readable medium, of the processor in some embodiments comprises one or more of readily available memory such as random access memory (RAM), read-only memory (ROM), floppy disk, hard disk, or any other form of digital storage, local or remote. The memory 194 of some embodiments is configured to retain an instruction set that is operable by the processor 192 to control parameters and components of the system 100, 200. The support circuits 198 of some embodiments are coupled to the processor 192 for supporting the processor 192 in a conventional manner. Circuits 198 include, for example, cache, power supplies, clock circuits, input/output circuitry, subsystems, and the like.

Processes may generally be stored in the memory as a software routine that, when executed by the processor, causes the system to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the chamber operation such that the processes are performed.

In some embodiments, the controller 190 has one or more configurations to execute individual processes or sub-processes to perform the method or operate the system. The controller 190 can be connected to and configured to operate intermediate components to perform the functions of the methods. For example, the controller 190 of some embodiments is connected to and configured to control one or more of gas valves, actuators, motors, slit valves, vacuum control, etc.

The controller 190 of some embodiments has one or more configurations selected from: a configuration to measure pressure within an effluent stream using one or more pressure monitors; a configuration to control one or more valves; a configuration to evaluate valve control parameters based on pressure measurements from the pressure monitors; a configuration to control the pumps and/or pump assembly; and/or a configuration to control a flow of water into the water inlet lines or purge gas into the purge lines.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure include modifications and variations that are within the scope of the appended claims and their equivalents.

What is claimed is:

1. An exhaust system comprising:
at least one first chamber connection line;
a first chamber pressure drop downstream of and in fluid communication with each of the at least one first chamber connection line;
at least one second chamber connection line;
a second chamber pressure drop downstream of and in fluid communication with each of the at least one second chamber connection lines; and
an exhaust pump in fluid communication with and downstream of the first chamber pressure drop and second chamber pressure drop.

2. The exhaust system of claim 1, wherein the first chamber pressure drop and second chamber pressure drop comprise one or more of baffles or pumps.

3. The exhaust system of claim 1, wherein the exhaust pump comprises one or more of a turbo pump or roots blower.

4. The exhaust system of claim 1, further comprising pressure control valves in fluid communication with the at least one first chamber connector line and the at least one second chamber connection line upstream of the respective pressure drops.

5. The exhaust system of claim 4, further comprising at least one pressure monitor upstream of at least one of the pressure drops.

6. The exhaust system of claim 5, wherein there is at least one pressure monitor upstream of each of the pressure drops.

7. The exhaust system of claim 6, further comprising a controller connected to at least one of the pressure monitors or pressure control valves.

8. The exhaust system of claim 7, wherein the controller is configured to open or close the pressure control valves in response to signals from the pressure monitor.

9. The exhaust system of claim 4, further comprising a pressure monitor upstream of the pressure drop, a valve downstream of the pressure drop and upstream of a pre-pump junction.

10. An exhaust system comprising:
at least one first chamber connection line;
at least one second chamber connection line; and
an exhaust pump assembly comprising a first inlet, a second inlet, a first pump in fluid communication with the first inlet, a second pump in fluid communication with the second inlet, a first outlet line in fluid communication with and downstream of the first pump, a second outlet line in fluid communication with and downstream of the second pump, an exhaust pump assembly outlet line in fluid communication with and downstream of the first outlet line and the second outlet line so that a fluid flowing through the first outlet line and the second outlet line coflow through the exhaust pump assembly outlet line and through an outlet in the exhaust pump assembly.

11. The exhaust system of claim 10, wherein the exhaust pump assembly comprises one or more of a water line inlet or purge line inlet, the water line inlet in fluid communication with each of the first pump and second pump, the purge line inlet in fluid communication with each of the first pump and second pump, and one or more of a water line outlet or purge line outlet, the water line outlet in fluid communication with the first pump and the second pump, the purge line outlet in fluid communication with the first pump and the second pump.

12. The exhaust system of claim 11, wherein there are three inlets and three pumps and one outlet connected to each of the three pumps.

13. The exhaust system of claim 11, wherein there are four inlets and four pumps and one outlet connected to each of the four pumps.

14. The exhaust system of claim 11, wherein the pumps comprise roots blowers.

15. The exhaust system of claim 11, further comprising a valve in fluid communication with the at least one first chamber connector line and the at least one second chamber connection line upstream of the exhaust pump assembly.

16. The exhaust system of claim 15, further comprising a pressure monitor downstream of the valve and upstream of the exhaust pump assembly.

17. The exhaust system of claim 16, further comprising a controller connected to at least one of the exhaust pump assembly, pressure monitors or pressure control valves.

18. The exhaust system of claim 17, wherein the controller is configured to open or close the valves in response to signals from the pressure monitors.

19. The exhaust system of claim 18, wherein the controller is configured to control a flow of water into the water inlet lines or purge gas into the purge lines.

20. A non-transitory computer readable medium including instructions, that, when executed by a controller of an exhaust system, causes the exhaust system to perform one or more operations selected from: a configuration to measure pressure within an effluent stream using one or more pressure monitors; a configuration to control one or more valves; a configuration to evaluate valve control parameters based on pressure measurements from the pressure monitors; a configuration to control the pumps and/or pump assembly; and/or a configuration to control a flow of water into the water inlet lines or purge gas into the purge lines.
